(19) United States
(12) Patent Application Publication
(10) Pub. No.: US 2016/0248037 A1
(43) Pub. Date: Aug. 25, 2016

(54) ENCAPSULATING METHOD OF OLED SUBSTRATE AND OLED STRUCTURE

(71) Applicant: SHENZHEN CHINA STAR OPTOELECTRONICS TECHNOLOGY CO., LTD., Guangdong (CN)

(72) Inventors: Yawei LIU, Shenzhen, Guangdong (CN); Taipi WU, Shenzhen, Guangdong (CN); Yifan WANG, Shenzhen, Guangdong (CN)

(73) Assignee: Shenzhen China Star Optoelectronics Technology Co., Ltd., Shenzhen, Guangdong (CN)

(21) Appl. No.: 14/378,394

(22) PCT Filed: Jul. 2, 2014
(86) PCT No.: PCT/CN2014/081434

§ 371 Date: Aug. 13, 2014

(30) Foreign Application Priority Data
May 30, 2014 (CN) 201410236277.4

(51) Int. Cl. H01L 51/52; H01L 51/56

(52) U.S. Cl. CPC H01L 51/524; H01L 51/5259; H01L 51/56

(57) ABSTRACT

The present invention relates to an encapsulating method of OLED substrate and an OLED structure. The encapsulating method includes steps of: step 1: providing an OLED substrate (1) and an encapsulation cover plate (3), a top surface of the OLED substrate (1) having a metal cathode (135); step 2: performing a surface treatment onto the metal cathode (135) by ion bombardment to thereby form a metal oxide layer (5) on a surface of the metal cathode (135); step 3: coating an encapsulation glue (7) and disposing a filler (9) on the encapsulation cover plate (3); step 4: oppositely disposing and bonding the encapsulation cover plate (3) and the OLED substrate (1); and step 5: curing the encapsulation glue (7) by UV light illumination and thereby realizing the encapsulation of the OLED substrate (1) by use of the encapsulation cover plate (3).

### TECHNICAL FIELD

The present invention relates to the field of display, and particularly to an encapsulating method of OLED substrate and an OLED structure.

### DESCRIPTION OF RELATED ART

In the field of display technology, flat display technologies such as liquid crystal displays (LCDs) and organic light emitting diode (OLED) displays, etc. have gradually replaced cathode ray tube (CRT) displays. The planar light source technology is a new light source, which is close to mass production level. For the flat display and planar light source technologies, the bonding of two pieces of flat glass is a very important technology and the boding effect will directly affect the device performance.

An UV (ultraviolet) curing technology is an earliest and most commonly used technology for the encapsulation of LCDs and OLEDs, and has the following characteristics of: (a) without the use of solvent or using a small amount of solvent and thus the environmental pollution of solvent being reduced; (b) low energy consumption, low temperature curable and thus being suitable for heat-sensitive materials; and (c) high curing speed, high efficiency, applicable to high-speed production line, and small occupied area for the curing apparatus. However, since the UV glue used in UV curing process is an organic material, the molecular gap is large after curing, water vapor and oxygen are easy to enter inside of sealed cavity through the molecular gap. Therefore, the UV encapsulation is mainly suitable for the applications of less sensitivity of water vapor and oxygen, such as LCD applications. Since the OLED device is very sensitive to water vapor and oxygen, when adopting the UV encapsulation, a desiccant usually is added inside of the OLED device so as to reduce the water vapor entering inside of sealed region through the molecular gap and thereby extend the lifespan of OLED device.

A conventional UV encapsulation method is illustrated in FIG. 1, a desiccant 300 is formed on the encapsulation cover plate 100 and the encapsulation cover plate 100 is formed with a groove 101 in advance. Or as illustrated in FIG. 2, a layer of desiccant 300′ is coated on the encapsulation cover plate 110′ and then is dried. After that, the encapsulation cover plate with desiccant is oppositely assembled with a TFT substrate 200 together. However, the two conventional encapsulation methods are not suitable for top-emitting, resulting from degraded light transmission after the desiccant 300 absorbing water. In addition, as illustrated in FIGS. 1 and 2, the water vapor would move around after entering in the sealed body through the UV encapsulation glue 500, and is either absorbed by the desiccant 300 or absorbed onto a surface of an OLED device 400 formed on a top surface of the TFT substrate 200, so that the water vapor would cause damage of the OLED device 400 at the first time after entering in the sealed body.

Accordingly, an encapsulation method with filler on the basis of the UV encapsulation has been proposed in the industry. Referring to FIG. 3, the conventional UV encapsulation method with filler is no longer needed to form the groove 101 on the encapsulation cover plate 100 in advance like FIG. 1, the desiccant 300, 300′ is eliminated and the sealed body is fully filled with a filler 600 instead. The use of filler 600 not only increases the structural strength of the OLED device 400, but also slows the entering speed of water vapor and extends the lifespan of the OLED device 400. Moreover, the filler 600 can be added with a small amount of transparent desiccant so as to enhance the effect of slowing the water vapor and further extend the lifespan of the OLED device 400. However, the use of filler brings an undesirable consequence, i.e., an area filled with the filler would appear a round dark spot, which influences the display quality of OLED device. Reasons for the formation of the round dark spot may be that: (1) the filler reacts with the metal cathode of OLED device, resulting in deterioration of the cathode, the resistance thereof being increased and the conductivity thereof being decreased; (2) the filler penetrates through the metal cathode and enters into organic material layers of OLED device, causing deterioration of the conductivity of organic material and quenching of photons emitted from a light emitting layer in the organic material layers.

### SUMMARY

An objective of the present invention is to provide an encapsulating method of OLED substrate. The encapsulating method can prevent a filler from directly contacting with a metal cathode as well as penetrating into the metal cathode and an organic material layer of OLED device. The dark sport caused by filler in the prior art can be avoided, the display quality of OLED device can be improved and the lifespan of OLED device can be extended consequently.

Another objective of the present invention is to provide an OLED structure. The OLED structure can avoid the formation of dark sport caused by filler in the prior art, improve the display quality of OLED device and extend the lifespan of OLED device.

In order to achieve the above objectives, an encapsulating method of OLED substrate is firstly provided. The encapsulating method includes the following steps of:

step 1: providing an OLED substrate and an encapsulation cover plate, a top surface of the OLED substrate having a metal cathode;

step 2: performing a surface treatment on the metal cathode by ion bombardment to thereby form a metal oxide layer on a surface of the metal cathode;

step 3: coating an encapsulation glue and disposing a filler on the encapsulation cover plate;

step 4: oppositely bonding the encapsulation cover plate with the OLED substrate; and

step 5: curing the encapsulation glue by UV light illumination and thereby achieving the encapsulation of the OLED substrate by use of the encapsulation cover plate.

In an exemplary embodiment, the encapsulation glue is an UV glue.

In an exemplary embodiment, a thickness of the metal oxide layer is in the range of 1 nm to 30 nm.

In an exemplary embodiment, the encapsulation cover plate is a glass plate.

In an exemplary embodiment, the ion bombardment is performed in a vacuum environment, or a waterless nitrogen environment with a small amount of oxygen.

In an exemplary embodiment, the ion bombardment is performed in a ppm environmental closed chamber, a content of water is less than 10 ppm, and a content of oxygen is in the range of 100 ppm to 20,000 ppm.

In an exemplary embodiment, the steps 2, 3, 4 and 5 all are performed in ppm environments.

Furthermore, an OLED structure according to the present invention includes an OLED substrate, an encapsulation cover plate sealingly connected onto the OLED substrate, and a filler disposed between the OLED substrate and the encapsulation cover plate. A top surface of the OLED substrate has a metal cathode, and a surface of the metal cathode has a thin metal oxide layer.

In an exemplary embodiment, the thin metal oxide layer is formed on the surface of the metal cathode by ion bombardment.

In an exemplary embodiment, a thickness of the thin metal oxide layer is in the range of 1 nm to 30 nm.

In an exemplary embodiment, the filler contains a transparent desiccant.

In addition, another OLED structure according to the present invention includes an OLED substrate, an encapsulation cover plate sealingly bonded with the OLED substrate, and a filler disposed between the OLED substrate and the encapsulation cover plate. A top surface of the OLED substrate has a metal cathode, and a surface of the metal cathode has a thin metal oxide layer. The thin metal oxide layer is formed on the surface of the metal cathode by ion bombardment. The thin metal oxide layer has a thickness in the range of 1 nm to 30 nm. The filler contains a transparent desiccant.

In sum, the encapsulating method of OLED substrate according to the present invention performs a surface treatment by ion bombardment on the metal cathode to thereby form a thin metal oxide layer on the surface of the metal cathode, and then performs an encapsulation process with filler. Since the thin metal oxide layer has a dense structure, which can prevent the filler from directly contacting with the metal cathode as well as penetrating into the metal cathode and an organic layer of OLED device. Accordingly, the dark sport caused by filler in the prior art can be avoided, the display quality of OLED device can be improved and the lifespan of OLED device can be extended. Moreover, the present encapsulating method is simple and easy to operate. In addition, the OLED structure according to the present invention is formed with a thin metal oxide layer on the surface of the metal cathode, which can avoid the formation of dark sport caused by filler in the prior art and thereby improve the display quality of OLED device and extend the lifespan of OLED device.

### BRIEF DESCRIPTION OF THE DRAWINGS

The above embodiments will become more readily apparent to those ordinarily skilled in the art after reviewing the following detailed description and accompanying drawings.

FIG. 1 is a schematic view of a conventional UV encapsulation method.

FIG. 2 is a schematic view of another conventional UV encapsulation method.

FIG. 3 is a schematic view of a conventional UV encapsulation method with filler.

FIG. 4 is a flow chart of an encapsulating method of OLED substrate according to the present invention.

FIG. 5 is a schematic perspective view of step 1 of the encapsulating method of OLED substrate according to the present invention.

FIG. 6 is a schematic cross-sectional view of step 1 of the encapsulating method of OLED substrate according to the present invention.

FIG. 7 is a schematic perspective view of step 2 of the encapsulating method of OLED substrate according to the present invention.

FIG. 8 is a schematic cross-sectional view of step 2 of the encapsulating method of OLED substrate according to the present invention.

FIG. 9 is a schematic perspective view of step 3 of the encapsulating method of OLED substrate according to the present invention.

FIG. 10 is a schematic perspective view of step 4 of the encapsulating method of OLED substrate according to the present invention.

FIG. 11 is a schematic cross-sectional view of an OLED structure according to the present invention.

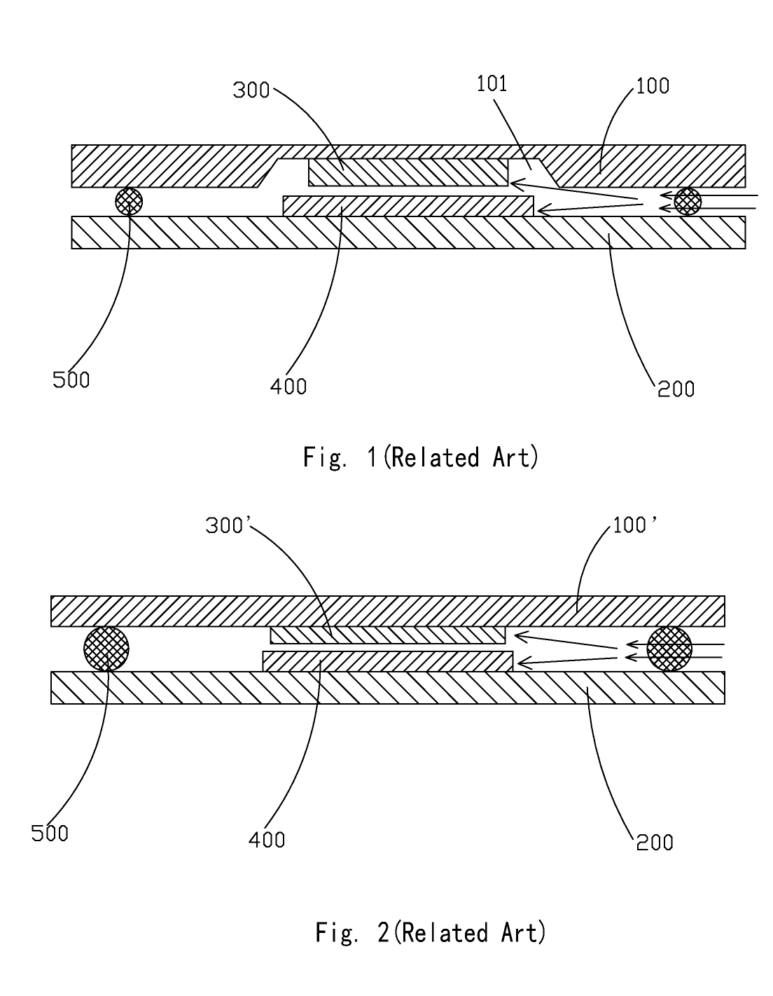

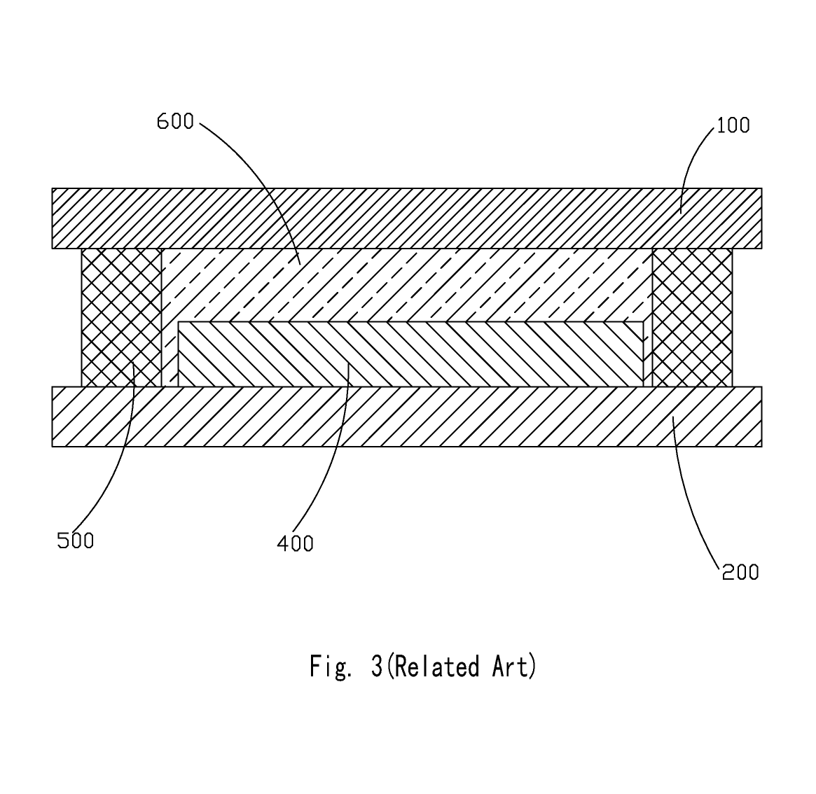

### DETAILED DESCRIPTION OF EMBODIMENTS

The present invention will now be described more specifically with reference to the following embodiments. It is to be noted that the following descriptions of embodiments are presented herein for purpose of illustration and description only. It is not intended to be exhaustive or to be limited to the precise form disclosed.

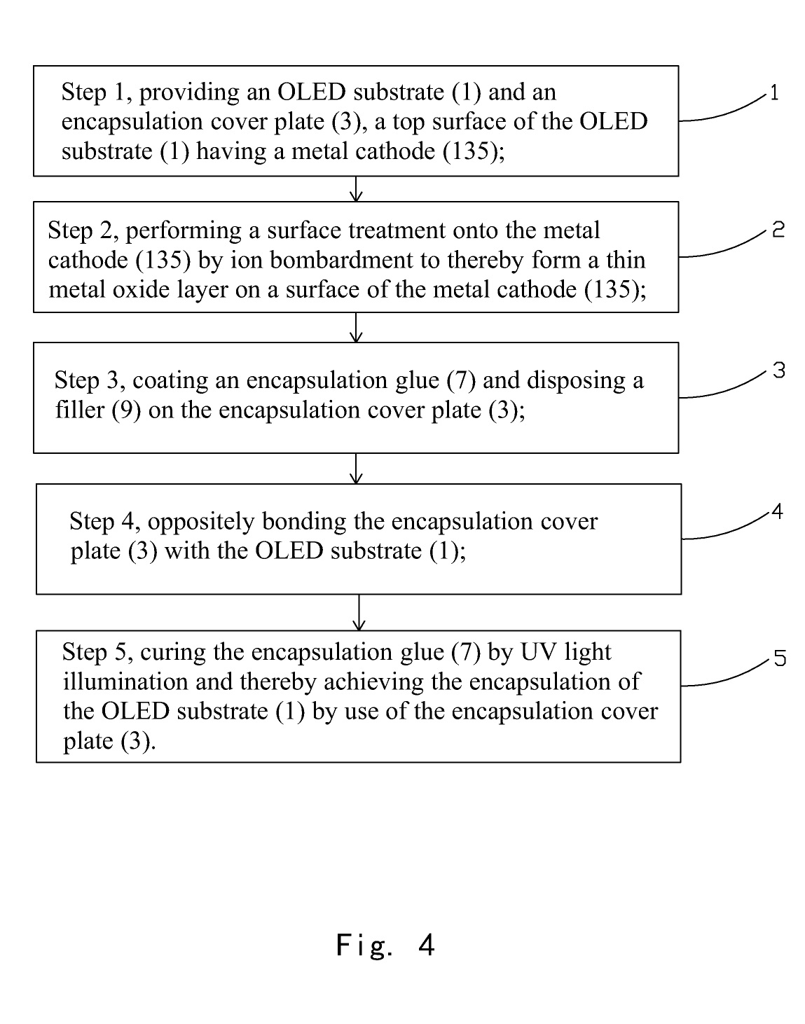

Referring to FIGS. 4 through 10, an encapsulating method of an OLED substrate includes the following steps of:

step 1: providing an OLED substrate 1 and an encapsulation cover plate 3, a top surface of the OLED substrate 1 having a metal cathode;

step 2: performing a surface treatment on the metal cathode 135 by ion bombardment to thereby form a thin metal oxide layer 5 on a surface of the metal cathode 135;

step 3: coating an encapsulation glue 7 on the encapsulation cover plate 3 and disposing a filler 9 on the encapsulation cover plate 3 in a region surrounded by the encapsulation glue 7;

step 4: oppositely bonding the encapsulation cover plate 3 with the OLED substrate 1; and

step 5: curing the encapsulation glue 7 by UV light illumination and thereby achieving the encapsulation of the OLED substrate 1 by use of the encapsulation cover plate 3.

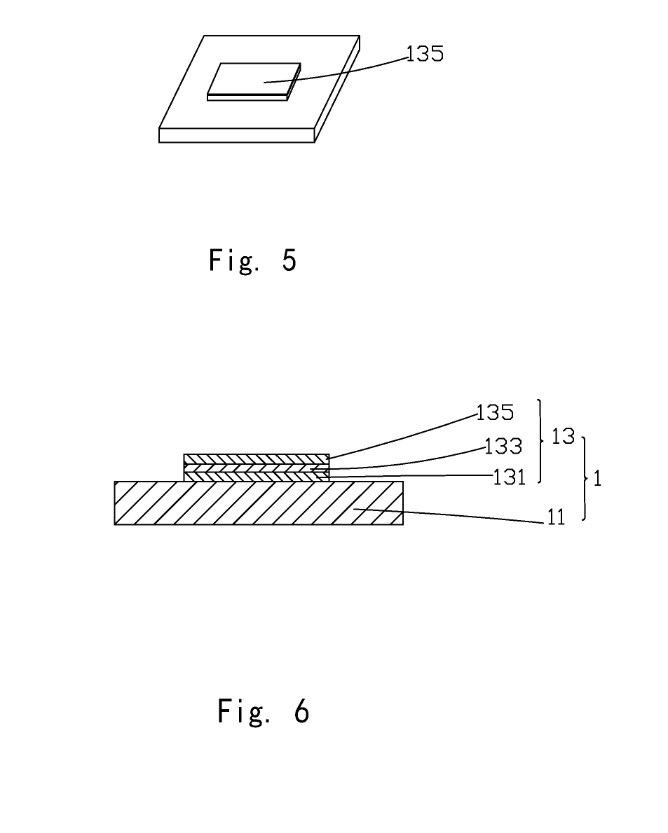

Specifically, as illustrated in FIGS. 5 and 6, the OLED substrate 1 in the step 1 includes a TFT substrate 11 and an OLED device 13. The OLED device 13 includes an anode, an organic material layer 133 and a metal cathode 135 arranged on the TFT substrate 11 in that order. The OLED device 13 is formed on the TFT substrate 11 by an evaporation process and thereby together forming the OLED substrate 1. The metal cathode 135 is made of a material such as aluminum (Al), silver (Ag) or gold (Au).

The encapsulation cover plate 3 can be a glass plate or a metal plate. Preferably, the encapsulation cover plate 3 is a glass plate.

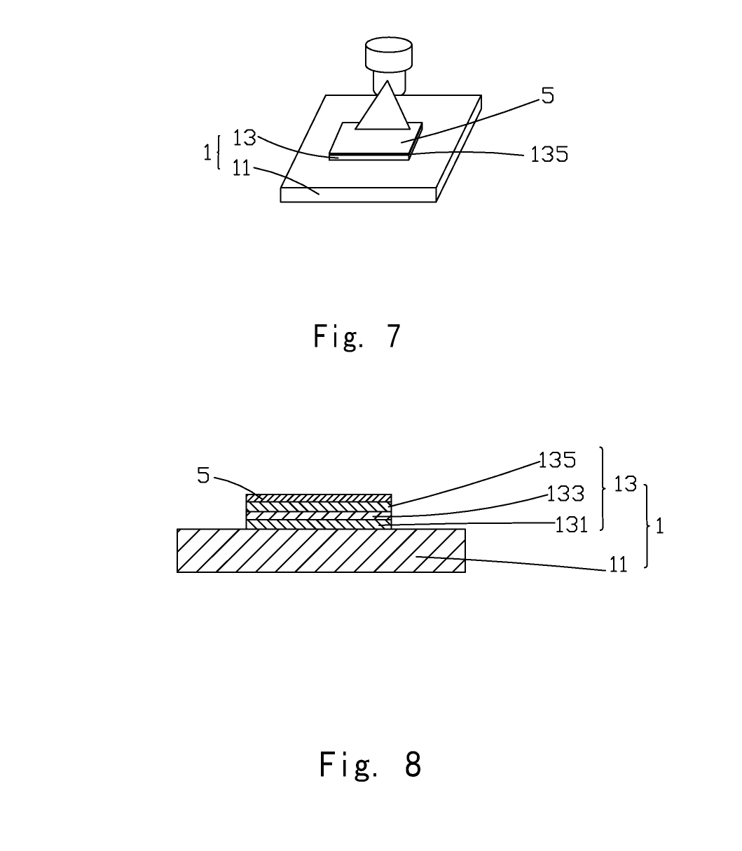

As illustrated in FIGS. 7 and 8, in the step 2, the metal cathode 135 is performed with surface treatment by ion bombardment to thereby form the thin metal oxide layer 5 on the surface of the metal cathode 135. The surface treatment by ion bombardment can be performed in a vacuum environment, or a waterless nitrogen environment with a small amount of oxygen. It is indicated that, the ion bombardment surface treatment needs to be performed in a closed chamber of ppm (parts per million) environment. The ppm environment is that contents and concentrations of various components within the environment are strictly controlled and measured with a unit of one millionth (i.e., ppm). The waterless nitrogen ppm environment with a small amount of oxygen is taken as an example, the ion bombardment surface treatment is performed in a closed chamber of ppm environment, the content of water is controlled to be less than 10 ppm, and the content of oxygen is controlled to be in the range of 100 ppm-20,000 ppm.

After the ion bombardment surface treatment, the metal cathode 135 is formed with a uniform and dense thin metal oxide layer 5 on its surface, a thickness of the metal oxide layer 5 is in the range of 1 nm to 30 nm.

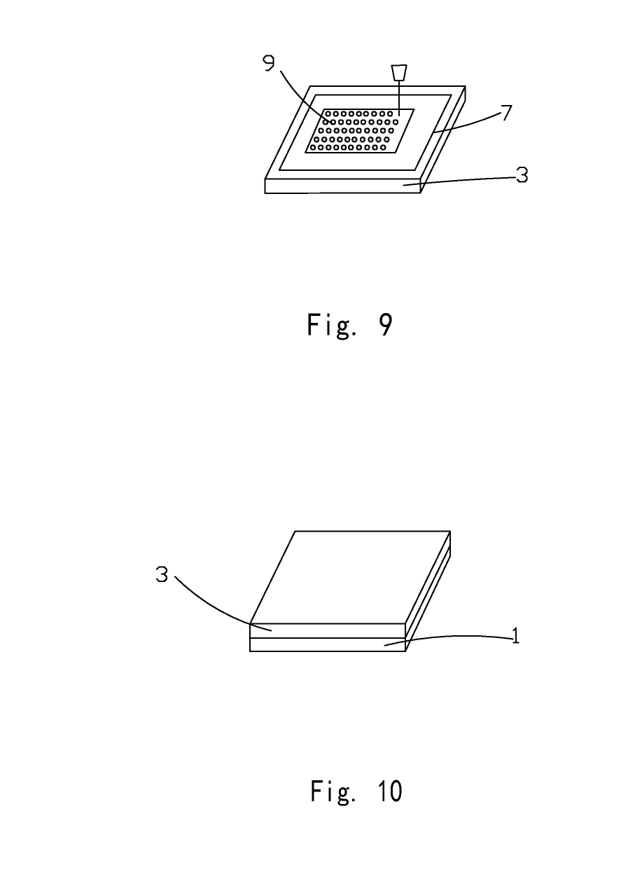

As illustrated in FIG. 9, after the metal oxide layer 5 is formed, the step 3 is started and an encapsulation glue 7 is coated on a peripheral region of the encapsulation cover plate 3. The encapsulation glue 7 is an UV glue. For example, the encapsulation glue 7 is an epoxy resin.

In the step 3, besides the coating of the encapsulation glue 7 on the encapsulation cover plate 3, a filler 9 is disposed on the encapsulation cover plate 3 in a region surrounded by the encapsulation glue 7. The filler 9 contains a transparent desiccant. The effect of filler 9 is to enhance the structural strength of the OLED device and slow the entering speed of water vapor.

Subsequently, as illustrated in FIG. 10, the step 4 is carried out. In the step 4, the encapsulation cover plate 3 and the OLED substrate 1 are disposed opposite to each other and bonded together. Finally, the coated encapsulation glue 7 is cured by UV light illumination and thereby finishing the encapsulation of the OLED substrate 1 by use of the capsulation cover plate 3.

It is indicated that, the steps 3, 4, 5 preferably are performed in ppm environments.

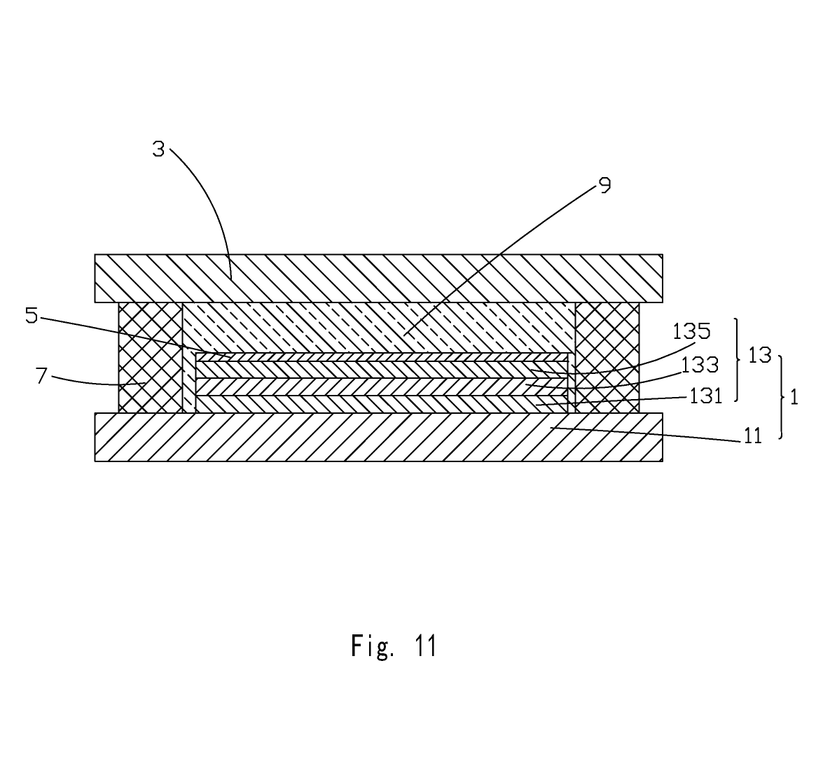

Referring to FIG. 11, based on the above encapsulating method of OLED substrate, an OLED structure also is proposed by the present invention. In particular, the OLED structure includes an OLED substrate 1, an encapsulation cover plate 3 sealingly connected onto the OLED substrate 1, a filler 9 disposed between the OLED substrate 1 and the encapsulation cover plate 3, and a thin metal oxide layer 5. The OLED substrate 1 includes a TFT (thin film transistor) substrate 111 and an OLED device 13. The OLED device 13 includes an anode 131, an organic material layer 133, and a metal cathode 135 formed on the TFT substrate 11 in that order. The thin metal oxide layer 5 is formed on the surface of the metal cathode 135.

The thin metal oxide layer 5 is formed on the surface of the metal cathode 135 by ion bombardment surface treatment.

The thin metal oxide layer 5 has a thickness in the range of 1 nm to 30 nm.

The encapsulation cover plate 3 is a glass plate.

The filler 9 contains a transparent desiccant.

In summary, the encapsulating method of OLED substrate according to the present invention performs a surface treatment onto the metal cathode by ion bombardment to form a thin metal oxide layer on the surface of the metal cathode and then performs the encapsulating process with filler. The thin metal oxide layer has a dense structure, which can prevent the filler from directly contacting with the metal cathode as well as penetrating into the metal cathode and the organic material layer. As a result, the dark spot caused by the filler in the prior art can be avoided, the display quality of OLED device can be improved and the lifespan of OLED device can be extended. Moreover, the encapsulating method according to the present invention is simple and easy to operate. In addition, the OLED structure according to the present invention is with a thin metal oxide layer formed on the surface of OLED metal cathode, which can avoid the formation of dark spot caused by the filler in the prior art, and thereby improve the display quality of OLED device as well as extend the lifespan of OLED device.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An encapsulating method of OLED substrate, comprising steps of:
step 1: providing an OLED substrate and an encapsulation cover plate, wherein a top surface of the OLED substrate has a metal cathode;
step 2: performing a surface treatment onto the metal cathode by ion bombardment to thereby form a metal oxide layer on a surface of the metal cathode;
step 3: coating an encapsulation glue and disposing a filler on the encapsulation cover plate;
step 4: oppositely bonding the encapsulation cover plate with the OLED substrate; and
step 5: curing the encapsulation glue by UV light illumination and thereby achieving the encapsulation of the OLED substrate by use of the encapsulation cover plate.

2. The encapsulating method as claimed in claim 1, wherein the encapsulation glue is an UV glue.

3. The encapsulating method as claimed in claim 1, wherein a thickness of the metal oxide layer is in the range of 1 nm to 30 nm.

4. The encapsulating method as claimed in claim 1, wherein the encapsulation cover plate is a glass plate.

5. The encapsulating method as claimed in claim 1, wherein the ion bombardment is performed in a vacuum environment, or a waterless nitrogen environment with a small amount of oxygen.

6. The encapsulating method as claimed in claim 5, wherein the ion bombardment is performed in a ppm environmental closed chamber, a content of water is less than 10 ppm and a content of oxygen is in the range of 100 ppm to 20,000 ppm

7. The encapsulating method as claimed in claim 1, wherein the steps 2, 3, 4 and 5 all are performed in ppm environments.

8. An OLED structure comprising:
an OLED substrate;
an encapsulation cover plate sealingly connected onto the OLED substrate; and
a filler disposed between the OLED substrate and the encapsulation cover plate;
wherein a top surface of the OLED substrate has a metal cathode, and a surface of the metal cathode is formed with a metal oxide layer.

9. The OLED structure as claimed in claim 8, wherein the metal oxide layer is formed on the surface of the metal cathode by ion bombardment.

10. The OLED structure as claimed in claim 8, wherein the metal oxide layer has a thickness in the range of 1 nm to 30 nm, and the filler contains a transparent desiccant.

11. An OLED structure comprising:
an OLED substrate;
an encapsulation cover plate sealingly bonded with the OLED substrate; and
a filler disposed between the OLED substrate and the encapsulation cover plate;
wherein a top surface of the OLED substrate has a metal cathode and a surface of the metal cathode has a metal oxide layer;
wherein the metal oxide layer is formed on the surface of the metal cathode by ion bombardment;
wherein the metal oxide layer has a thickness in the range of 1 nm to 30 nm, and the filler contains a transparent desiccant.
